(19) United States
(12) Patent Application Publication
(10) Pub. No.: US 2026/0073987 A1
(43) Pub. Date: Mar. 12, 2026

(54) NON-VOLATILE MEMORY DEVICE AND OPERATING METHOD THEREOF

(71) Applicant: SAMSUNG ELECTRONICS CO., LTD., SUWON-SI (KR)

(72) Inventors: JONGMIN KIM, Suwon-si (KR); YOHAN LEE, Suwon-si (KR); HYUN JUN YOON, Suwon-si (KR); WOOSUL SHIN, Suwon-si (KR)

(21) Appl. No.: 19/315,933

(22) Filed: Sep. 2, 2025

(30) Foreign Application Priority Data
Sep. 6, 2024 (KR) 10-2024-0121658

(51) Int. Cl. G11C 16/08; G11C 16/26; G11C 16/34

(52) U.S. Cl. CPC G11C 16/08; G11C 16/26; G11C 16/3454

(57) ABSTRACT

a non-volatile memory device comprising a memory cell array including a first physical page and a second physical page, wherein the first physical page includes first memory cells connected to the first word line and the second physical page includes second memory cells connected to the first word line, a row decoder configured to sequentially perform a first program operation on the first memory cells of the first physical page and perform a second program operation on the second memory cells of the second physical page, a page buffer circuit configured to perform an accumulation operation on first and second data for generating a accumulated data, and to perform a verify operation on the first and second memory cells based on the accumulated data, and a control logic configured to determine whether the first and second memory cells passed the program operations based on the result of the verify operation.

### CROSS-REFERENCE TO RELATED APPLICATION

This application claims priority under 35 U.S.C. § 119 to Korean Patent Application No. 10-2024-0121658, filed on Sep. 6, 2024, in the Korean Intellectual Property Office, the disclosure of which is incorporated by reference herein in its entirety.

### TECHNICAL FIELD

The present disclosure relates to a non-volatile memory device and an operating method thereof.

### DESCRIPTION OF THE RELATED ART

Semiconductor memory devices may be categorized into volatile memory devices and non-volatile memory devices. Although the volatile memory devices have advantage in read and write speeds, they may lose stored data when external power supply is cut off. On the other hand, the non-volatile memory devices are relatively slow in read and write speeds. However, they may retain stored data even when external power supply is cut off.

More particularly, the non-volatile memory devices such as flash memory devices have some advantages such as large capacity, low noise, and low power. For making the most of the advantages, flash memory devices support various operation modes applicable to various computing systems.

### SUMMARY

An embodiment of the present disclosure provides a non-volatile memory device comprising a memory cell array including a first physical page and a second physical page in which each of the first and second physical pages is a unit of a program operation and the first physical page is selected by a first word line and a first string selection line and the second physical page that is selected by the first word line and a second string selection line different from the first string selection line, wherein the first physical page includes first memory cells connected to the first word line and the second physical page includes second memory cells connected to the first word line, a row decoder configured to sequentially perform a first program operation on the first memory cells of the first physical page and perform a second program operation on the second memory cells of the second physical page, a page buffer circuit including a sense latch and a data latch connected to the first and second physical pages, and the page buffer circuit configured, during the first program operation, to store first data in the sense latch and in the data latch for programming the first data into the first memory cells of the first physical page, and during the second program operation to store second data in the sense latch for programming the second data into the second memory cells of the second physical page and to perform an accumulation operation on the first and second data for generating a first accumulated data and storing the first accumulated data into the data latch, and to perform a verify operation on the first and second memory cells based on the first accumulated data, and a control logic configured to determine whether the first and second memory cells passed the program operations based on the result of the verify operation.

Another embodiment of the present disclosure provides a non-volatile memory device comprising a memory cell array including a first physical page, a second physical page, and a third physical page in which each of the first to third physical pages is a unit of a program operation and the first physical page is selected by a first word line and a first string selection line, the second physical page that is selected by the first word line and a second string selection line, and the third physical page that is selected by the first word line and a third string selection line, wherein the first physical page includes first memory cells, the second physical page includes second memory cells, and the third physical page includes third memory cells, and the first to third memory cells are connected to the first word line, a row decoder configured to sequentially perform a first program operation on the first memory cells of the first physical page, perform a second program operation on the second memory cells of the second physical page, and perform a third program operation on the third memory cells of the third physical page, a page buffer circuit configured to include first to third data latches connected to the first to third physical pages, to store first data in the first latch in response to the first physical page being selected, to store second data in the second data latch in response to the second physical page being selected, and to store third data in the third data latch in response to the third physical page being selected, and to perform a verify operation based on accumulated data generated based on the first to third data, and a control logic configured to determine whether the first to third memory cells passed the program operations based on the result of the verify operation.

Another embodiment of the present disclosure provides an operating method of a non-volatile memory device including performing a setup operation of first data for a first physical page selected based on a first word line and a first string selection line, applying a program voltage to the first physical page, performing a setup operation of second data for a second physical page selected based on the first word line and a second string selection line different from the first string selection line, performing a data accumulation operation based on the first and second data to generate accumulated data, applying a program voltage to the second page, checking whether the second page is a last page, upon determining the second page as the last page, selecting a first page buffer among a plurality of page buffers connected to the first physical page, performing a verify operation on a plurality of memory cells connected to the first page buffer, and determining whether the first and second physical pages pass based on result of the verify operation.

### BRIEF DESCRIPTION OF THE DRAWINGS

FIG. 1 illustrates a block diagram of a storage device according to an embodiment.

FIG. 2 illustrates a block diagram of a storage controller according to an embodiment.

FIG. 3 illustrates a block diagram of a non-volatile memory device according to an embodiment.

FIG. 4 illustrates a circuit diagram of a memory block according to an embodiment.

FIG. 5 is a drawing for describing the threshold voltage distribution of memory cells within a physical page of FIG. 4.

FIG. 6 illustrates a block diagram of a page buffer according to an embodiment.

FIG. 7 illustrates a flowchart of an operation method of a non-volatile memory device according to an embodiment.

FIG. 8 illustrates a timing diagram of an operation method of a non-volatile memory device according to an embodiment.

FIG. 9 to FIG. 12 are drawings for describing an operating method of a non-volatile memory device according to an embodiment.

FIG. 13 illustrates a flowchart of an operation method of a non-volatile memory device according to an embodiment.

FIG. 14 illustrates a timing diagram of an operation method of a non-volatile memory device according to an embodiment.

FIG. 15 is a drawing for describing an operating method of a non-volatile memory device according to an embodiment.

FIG. 16 illustrates a timing diagram of an operation method of a non-volatile memory device according to an embodiment.

FIG. 17 illustrates a block diagram of a solid state drive (SSD) system to which a storage device according to an embodiment is applicable.

FIG. 18 illustrates a block diagram of a data center to which a storage device according to an embodiment is applicable.

### DETAILED DESCRIPTION OF THE EMBODIMENTS

The present disclosure will be described more fully hereinafter with reference to the accompanying drawings. The described embodiments may be modified in different ways without departing from the spirit or scope of the present disclosure.

In the present disclosure, parts or portions that are irrelevant to the description are omitted, and identical or similar constituent elements throughout the specification are denoted with the same reference numerals.

In addition, unless explicitly stated to the contrary, the word “comprise” and variations such as “comprises” and “comprising” should be understood to imply the inclusion of stated elements but not the exclusion of any other elements.

It will be further understood by those within the art that if a specific number of an introduced claim recitation is intended, such an intent will be explicitly recited in the claim, and in the absence of such recitation no such intent is present. For example, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (for example, “a” and/or “an” should be interpreted to mean “at least one” or “one or more”), the same holds true for the use of definite articles used to introduce claim recitations.

Furthermore, in those instances where a convention analogous to “at least one of A, B, or C” is used, in general such a construction is intended in the sense one having skill in the art would understand the convention, for example, “a system having at least one of A, B, or C” would include but not be limited to systems that have A alone, B alone, C alone, A and B together, A and C together, B and C together, and/or A, B, and C together. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In an embodiment of the disclosure, the terms “module”, “unit” and/or “part” are terms to refer to an element performing at least one function or operation and may be implemented as hardware, software, or a combination of hardware and software.

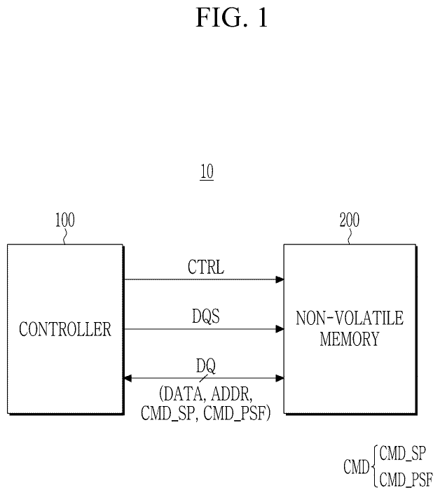

FIG. 1 illustrates a block diagram of a storage device according to an embodiment.

Referring to FIG. 1, a storage device 10 includes a controller 100 and a non-volatile memory device 200. The non-volatile memory device 200 may be connected to the controller 100 through a plurality of channels, and several non-volatile memory devices 200 may be connected to each channel.

The controller 100 controls read operation and the program operation for the non-volatile memory device 200. For example, the controller 100 may transmit a command CMD, an address ADDR, and program data PDATA to the non-volatile memory device 200 using a plurality of data signals DQ during program operation. Alternatively, the controller 100 may transmit a command CMD and an address ADDR to the non-volatile memory device 200 using a plurality of data signals DQ and receive read data RDATA from the non-volatile memory device 200 during read operation or verify operation. The term “data DATA” may refer to one of the program data PDATA and the read data RDATA or refer to both the program data PDATA and the read data RDATA.

The controller 100 transmits a control signal CTRL and a data strobe signal DQS to the non-volatile memory device 200. For example, the control signal CTRL, the data strobe signal DQS, and the plurality of data signals DQ may be transmitted to the non-volatile memory device 200 through signal lines dedicated to those signals. The control signal CTRL and the data strobe signal DQS may be distinguished from the plurality of data signals DQ transmitted from the controller 100 to the non-volatile memory device 200 or transmitted from the non-volatile memory device 200 to the controller 100.

The non-volatile memory device 200 may receive program data PDATA from the controller 100 or transmit read data RDATA to the controller 100 in response to the control signal CTRL, the data strobe signal DQS, and the plurality of data signals DQ. The non-volatile memory device 200 may identify the command CMD, address ADDR, or data DATA of the plurality of data signals DQ using the control signal CTRL.

The non-volatile memory device 200 may include a NAND flash memory. However, the scope of the present disclosure is not limited thereto, and the non-volatile memory device 200 may include volatile or non-volatile memory devices such as a static RAM (DRAM), a dynamic RAM (DRAM), a synchronous DRAM (SDRAM), a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), and a ferroelectric RAM (FRAM).

According to an embodiment, the non-volatile memory device 200 may include a plurality of memory blocks that are separated by different data regions and different types of memory cells. The plurality of memory blocks may include a single-level cell memory block including a single-level cell (SLC) that stores 1-bit data, a multi-level cell memory block including a multi-level cell (MLC) that stores 2-bit data, a triple-level cell memory block including a triple-level cell (TLC) that stores 3-bit data, and a quadruple-level cell memory block including a quadruple-level cell (QLC) that stores 4-bit data. For example, the non-volatile memory device 200 may include both a single-level cell memory block and a triple-level cell memory block.

According to an embodiment, the command CMD may instruct operations for the non-volatile memory device 200 to perform. For example, the command CMD may include an SLC program command CMD_SP, a program status check command CMD_PSF, and a command for data latch control. The SLC program command CMD_SP may be a command requesting a program operation based on SLC caching, SLC mode, or a command requesting a program operation for a meta area in which metadata and mapping data are stored. The program status check command CMD_PSF may be a command requesting program status fail (PSF) information that indicates a program operation pass or program operation fail of memory blocks on which program operation and verify operation are performed.

According to an embodiment, the non-volatile memory device 200 may perform a program operation by applying a program voltage to a physical page. The physical page may include single level cells SLCs and may be programmed based on the SLC program command CMD_SP. The SLCs may be programmed through a sequence of program operations and verify operations. More particularly, the non-volatile memory device 200 perform a predetermined number of program operations on a memory block and perform a verify operation on the memory block based on accumulated data of previously performed program operations and determine whether the memory block passed the program operations.

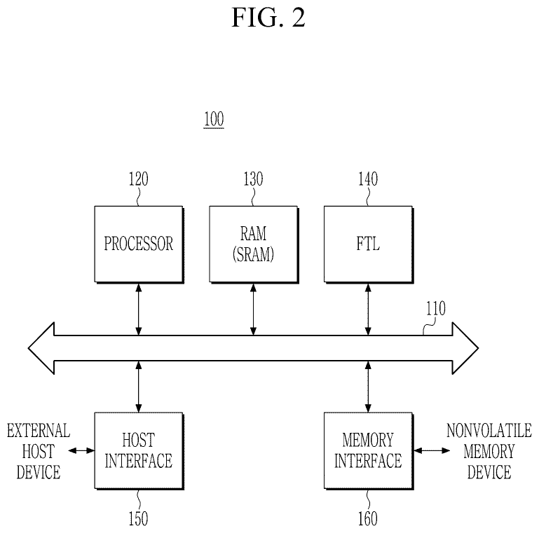

FIG. 2 illustrates a block diagram of a storage controller according to an embodiment.

Referring to FIG. 2, a controller 100 may include a bus 110, a processor 120, a random access memory (RAM) device 130, a flash translation layer 140 (FTL), a host interface 150, and a memory interface 160.

The bus 110 may provide a channel between components of the controller 100.

The processor 120 may control an overall operation of the controller 100 and perform logical operations. The processor 120 may communicate with an external host device through the host interface 150 and may communicate with a non-volatile memory device 200 through the memory interface 160.

The RAM device 130 may be used as an operating memory, cache memory, or buffer memory of the processor 120. The RAM device 130 may store codes and commands executed by the processor 120. The RAM device 130 may store data processed by the processor 120. The RAM device 130 may be a static RAM (SRAM) or a dynamic RAM (DRAM).

The FTL 140 may provide an interface between the host device and the non-volatile memory device 200 for efficient use of the non-volatile memory device 200 as described below. The FTL 140 may perform address mapping operation, garbage collection operation, wear leveling operation, read reclaim operation, and log operation for deterioration information of memory block unit or sub-block as a memory management module.

According to an embodiment, the FTL 140 may be implemented in hardware with a dedicated circuit, but may also be implemented in software. When implemented in software, the FTL may be loaded into the RAM device 130 to be used by the processor 120. For example, the FTL 140 stored in the RAM device 130 may include an address mapping table for operating the processor 120.

The host interface 150 is configured to communicate with an external host device under the control of the processor 120. The host interface 150 may be configured to communicate using communication methods such as universal serial bus (USB), serial ATA (SATA), serial attached SCSI (SAS), high speed interchip (HSIC), small computer system interface (SCSI), peripheral component interconnection (PCI), PCIexpress (PCIe), non-volatile memory express (NVMe), universal flash storage (UFS), secure digital (SD), multimedia card (MMC), embedded MMC (eMMC), dual in-line memory module (DIMM), registered DIMM (RDIMM), and a load reduced DIMM (LRDIMM).

The memory interface 160 is configured to communicate with the non-volatile memory device 200 under the control of the processor 120. As described with reference to FIG. 1, the memory interface 160 may be used for transmitting or receiving commands CMD, addresses ADDR, and data DATA to or from the non-volatile memory device 200 through input/output channels. The memory interface 160 may also be used for transmitting control signals CTRL to the non-volatile memory device 110 through a control channel.

Although this embodiment exemplifies that the storage device 10 includes a RAM device 130, the storage device 10 may further include a separate memory device such as DRAM device connected to the controller 100, and the controller 100 may further include a buffer control circuit for controlling the separate memory device. However, such the separate memory device is not regarded as an essential element of the storage device 10. For example, a storage device not including such a separate memory device outside the controller 100 is referred as a “DRAMless” storage device.

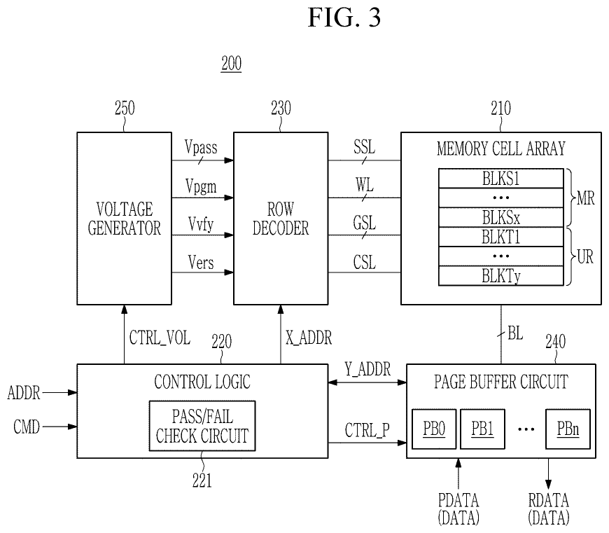

FIG. 3 illustrates a block diagram of a non-volatile memory device according to an embodiment.

Referring to FIG. 3, a non-volatile memory device 200 may include a memory cell array 210, a control logic 220, a row decoder 230, a page buffer circuit 240, and a voltage generator 250. Although not shown in FIG. 3, the non-volatile memory device 200 may further include a memory interface circuit, a column logic, a pre-decoder, a temperature sensor, a command decoder, and an address decoder.

A bit line BL of the memory cell array 210 may be connected to a corresponding page buffer circuit 240. A plurality of word lines WL of the memory cell array 210 may be connected to a row decoder 230. The row decoder 230 may select one of the plurality of word lines and select one of a plurality of string selection lines SSL for selecting a string among the plurality of cell strings coupled to the plurality of word lines and select one of a plurality of ground selection lines GSL and connect the selected ground selection line to a common source line CSL for providing the selected cell string with ground level voltage.

The memory cell array 210 may include a plurality of memory blocks including a plurality of memory cells. The memory cells referred in the present disclosure may be flash memory cells, more particularly, NAND flash memory cells. However, the present disclosure is not limited thereto, and the plurality of memory cells may be resistive memory cells such as a resistive RAM (ReRAM) and a phase change RAM (PRAM), a ferroelectric RAM (FRAM), or a magnetic RAM (MRAM).

The memory cell array 210 may include a meta region MR and a user region UR. The meta region MR may refer to a region that stores an address mapping table or metadata for recording characteristics of user data. The user region UR may refer to a region that stores user data. The user data refers to data used or generated in a software layer such as program codes, and files.

The meta region MR may include a plurality of single-level cell (SLC) memory blocks BLKS1 to BLKSx, where x is an integer greater than or equal to 2. Each of the memory blocks BLKS1 to BLKSx includes a plurality of SLCs. The user region UR may include a plurality of triple-level cell (TLC) memory blocks BLKT1 to BLKTy, where y is an integer greater than or equal to 2. However, the present disclosure is not limited thereto. Each memory block may include a plurality of physical pages, and each physical page may include a plurality of memory cells. Each memory block or sub-memory block may be a unit of an erase operation in which the memory cells of each memory block may be erased simultaneously. Each physical page may be a unit of a program operation, and the memory cells of each physical page may be programmed together.

When an erase voltage Vers is applied to the memory cell array 210, a plurality of memory cells may be in an erased status. A program voltage Vpgm is applied to the memory cell array 210, thereby the plurality of memory cells may be turned into a programmed status from the erased status. Each memory cell that is in an erased status and in a programmed status may be distinguished by a threshold voltage of each of the memory cells. As the number of bits that each memory cell can store is different depending on the memory cell types, the number of the programmed status may also be different. For example, when the memory cell is an SLC storing 1-bit data, the memory cell may have one of an erased status and a program status, and when the memory cell is a TLC storing 3-bit data, the memory cell in the programmed status may have an erased status or one of seven states in which the seven states may be distinguished from each other by different threshold voltages programmed on the memory cell. Though TLC example is described above, the types of the memory cells of the present disclosure may also include multi-level cell (MLC) and quadruple-level cell (QLC), and are not limited to the examples.

According to an embodiment, the memory cell array 210 may include a three-dimensional memory cell array, but the technical idea of the present disclosure is not limited thereto, and it may be a two-dimensional memory cell. The three-dimensional memory cell array may include a plurality of cell strings, and each cell string may include memory cells respectively connected to a plurality of word lines WL stacked vertically on a substrate.

The control logic 220 may control overall operations within the non-volatile memory device 200. The control logic 220 may output various control signals in response to the command CMD and/or the address ADDR received from the controller 100. The control logic 220 may output a control signal for programming the program data PDATA to the memory cell array 210, reading the read data RDATA from the memory cell array 210, or erasing data stored in the memory cell array 210. For example, the control logic 220 may output a voltage control signal CTRL_vol, a row address X-ADDR, a column address Y-ADDR, and a page buffer control signal CTRL_P.

The control signals from the control logic 220 may be provided to the voltage generator 250, the row decoder 230, and the page buffer circuit 240 respectively. The control logic 220 may provide the voltage control signal CTRL_vol to the voltage generator 250. The voltage control signal CTRL_vol may be used to control the generation of a program voltage Vpgm and a verify voltage Vvfy for performing a program operation and a verify operation.

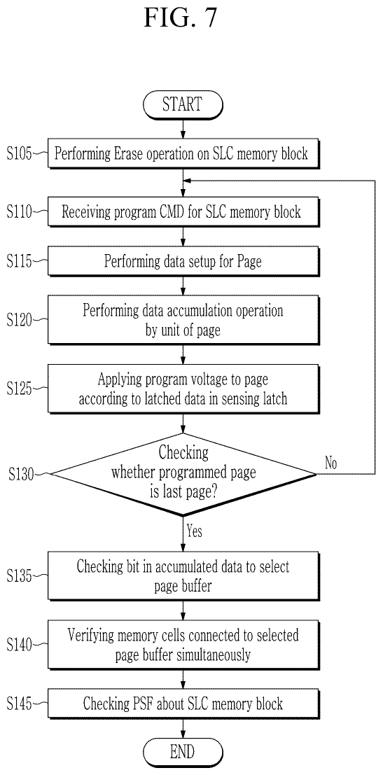

The control logic 220 may further include a pass/fail check circuit 221. The pass/fail check circuit 221 may check PSF information for a memory block that is a target of a verify operation based on the status information sensed and latched by the page buffer circuit 240 during the verify operation. The verify operation will be described in more detail with reference to FIG. 7 to FIG. 15.

According to an embodiment, the pass/fail check circuit 221 may compare the bit stored in the data latch with the sensed bit during the verify operation for the memory block.

According to an example embodiment, a program operation of a plurality of memory cells including first memory cells and second memory cells in a word line WL will be described. For programming the first memory cells, a program voltage Vpgm among a plurality of different program voltages is applied to the selected word line WL among the plurality of word lines WLs, and thereafter, for programming the second memory cells, the program voltage Vpgm is applied to the selected word line WL among the plurality of word lines WL. Applying a program voltage Vpgm to the plurality of memory cells coupled to the plurality of WLs of the non-volatile memory device 200 may be referred as a “program operation” or a “write operation.”

According to an embodiment, the control logic 220 may apply the verify voltage Vvfy to the selected word line WL after applying the program voltage Vpgm to memory cells coupled to at least two different cell strings sequentially. The program and verify operation may be performed differently on different memory cell types. For example, the control logic 220 may apply the verify voltage Vvfy to at least two cell strings of the single-level cell memory blocks BLKS1 to BLKSx simultaneously after applying the program voltage Vpgm to the at least two cell strings sequentially.

The control logic 220 may control the page buffer circuit 240 to latch received data from the controller 100 into a data latch in the page buffer circuit 240 and to accumulate the latched data and store the accumulated data into another data latch while the program voltage Vpgm is applied to a selected string of a selected word line WL. The accumulation operation may be performed by bit OR operation of received data and the accumulated data stored in a data latch.

According to an embodiment, the page buffer circuit 240 may apply a precharge voltage to the bit line BL based on the accumulated data stored in the data latch. More particularly, the accumulated data may correspond to each of the plurality of bit lines BL, and the page buffer circuit 240 may apply a precharge voltage to the plurality of bit lines BL based on the plurality of accumulated data.

The control logic 220 may control the page buffer circuit 240 to sense an off-cell or an on-cell of a memory cell in response to applying the verify voltage Vvfy. The off-cell may be a memory cell having a threshold voltage higher than the applied verify voltage Vvfy. The on-cell may be a memory cell having a threshold voltage lower than the applied verify voltage Vvfy.

During the sensing operation, the control logic 220 may control the page buffer circuit 240 to sense the voltage of the bit line BL and latch the sensing result together with the verify voltage Vvfy applied to a plurality of memory cells on which the verify operation is performed. The verify operation includes sensing of the target memory cell to decide whether the target memory cell is an off-cell or an on-cell, and providing the non-volatile memory device 200 with the precharge voltage and the verify voltage Vvfy. The precharge voltage may be provided by applying the precharge voltage to corresponding bit line connected to the memory cell and the verify voltage may be provided by applying the verify voltage Vvfy to corresponding word line WL connected to the memory cell.

According to an embodiment, the voltage generator 250 may perform a verify operation on memory cells of different physical pages simultaneously by selecting several string selection lines SSLs together. For example, when memory cells of different physical pages verified during a verify operation have threshold voltages higher than the verify voltage, the page buffer circuit 240 may sense an off-cell.

The voltage generator 250 may apply program voltage Vpgm to the memory cell array 210 on a selected word line among a plurality of word lines WLs. The voltage generator 250 may generate different voltage levels for performing program, read, and erase operations on the memory cell array 210 based on the voltage control signal CTRL_vol. The voltage generator 250 may generate, for example, a program voltage Vpgm, a verify voltage Vvfy, a pass voltage Vpass, and an erase voltage Vers. The voltage generator 250 may apply pass voltage Vpass to an unselected word line, a selected string selection line SSL, and a selected ground selection line GSL during a read or verify operation.

The voltage generator 250 may apply program voltage Vpgm and the verify voltage Vvfy to a selected word line among the plurality of word lines WL. The selected word line may be a word line selected based on a row address X-ADDR received by a row decoder 230.

The control logic 220 may transmit the row address X-ADDR to the row decoder 230 for selecting a specific word line among the plurality of word lines WLs. During a program operation, the row decoder 230 may apply the program voltage Vpgm to the selected word line. The row decoder 230 may further select a string selection lines SSL and/or a ground selection lines GSL in response to the row address X-ADDR.

According to an embodiment, when a plurality of program operations may be performed within one memory block. The row decoder 230 may perform the program operations sequentially by applying the program voltage Vpgm to several selected word lines WLs sequentially. The program data of each program operation is accumulated in page buffers. Thereafter, the verify voltage Vvfy may be applied to the several selected word lines WLs after the program operations performed sequentially. The row decoder 230 may apply the pass voltage Vpass to the remaining unselected word lines, the selected string selection line SSL, and the selected ground select line GSL while the verify voltage Vvfy is applied.

Referring to FIG. 3, a plurality of program operations may be performed on one of a plurality of single-level cell memory blocks BLKS1 to BLKSx, the row decoder 230 may apply the program voltage Vpgm to a selected word lines WL in an operation order by selecting a different string selection lines SSLs sequentially, and apply the verify voltage Vvfy to the word line WL in response to a plurality of accumulated program operations. The row decoder 230 may simultaneously select a ground selection line GSL corresponding to a plurality of different string selection lines SSL when the verify voltage Vvfy is applied to the selected word line WL.

The page buffer circuit 240 may be connected to the memory cell array 210 through the plurality of bit lines BL. The page buffer circuit 240 may select some of the plurality of bit lines BL in response to the column address Y-ADDR received from the control logic 210. During a program operation, the page buffer circuit 240 may operate as a write driver for latching data DATA to be programmed into the memory cell array 210, and during a read operation or a verify operation, the page buffer circuit 240 may operate as a sense amplifier to sense the data DATA stored in the memory cell array 210. The page buffer circuit 240 may selectively provide a bit line program voltage or a bit line inhibit voltage to the bit line BL according to the data DATA to be stored.

The page buffer circuit 240 may include a plurality of page buffers PB0 to PBN, where n is an integer, connected to the plurality of bit lines BL. The plurality of page buffers PB0 to PBN may be connected to corresponding bit line BL by received address ADDR during the program or read operation. Each page buffer may include a plurality of latch circuits to store data to be programmed into the memory cells or to store data sensed from the memory cells. Hereinafter, the page buffer circuit will be defined as including a page buffer connected to each bit line BL. However, the embodiments of the present disclosure may define the term differently, and a unit of a configuration in which one page buffer is provided to corresponding plurality of bit lines and corresponding each bit line may be defined as a page buffer unit.

The page buffer circuit 240 may store read data RDATA read from the memory cell array 210, or may store program data PDATA to be programmed in the memory cell array 210. The page buffer circuit 240 may latch the program data PDATA to be programmed into the data latch, and may accumulate the program data PDATA and latch the accumulated data into another data latch. The page buffer circuit 240 may apply a precharge voltage to the bit line BL based on the latched accumulated data during verify operation.

According to an embodiment, the page buffer circuit 240 may latch the program data PDATA to be programmed into a data latch, and accumulate the program data PDATA and store the accumulated data into another data latch in response to the SLC program command CMD_SP. The page buffer circuit 240 may check accumulated data whether the accumulated data is final and select one of a plurality of page buffers PB0 to PBN in which final accumulated data are stored. The page buffer circuit 240 may determine the accumulated data as a final accumulated data or a last accumulated data when the data DATA for programming the last physical page are accumulated with the previous accumulated data. The page buffer circuit 240 may perform a verify operation by selectively applying a precharge voltage to a bit line corresponding to the selected page buffer.

During the verify operation, the row decoder 230 may select the plurality of string selection lines SSL for applying the verify voltage to the memory cells coupled to the word line selected by the string selection lines SSL, and the page buffer circuit 240 may sense whether a plurality of memory cells are off-cells or on-cells. The control logic 220 may issue a program status command to check whether the memory block has passed the program operation based on the sensing result of the verify operation.

As the non-volatile memory device 200 may perform a verify operation cumulatively with respect to the plurality of program operations, the program operation speed may be improved while preserving reliability.

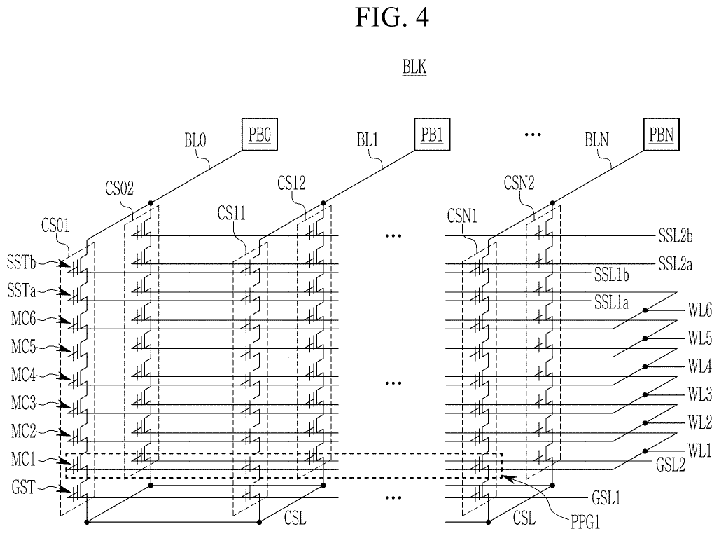

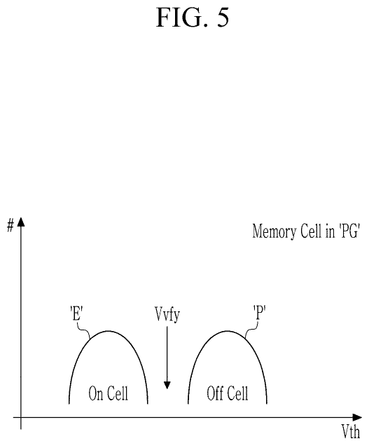

FIG. 4 illustrates a circuit diagram of a memory block according to an embodiment. FIG. 5 is a drawing for describing the threshold voltage distribution of memory cells within a physical page of FIG. 4. The memory block BLK may be a single-level cell memory block in which memory cells store one-bit data. The memory BLK may be one of memory cell blocks BLKS1 to BLKSx shown in FIG. 3.

Referring to FIG. 4, the memory block BLK may include a plurality of cell strings CS01 to CSN1 and CS02 to CSN2 arranged in a first direction D1.

The cell strings CS01 to CSN1 arranged along the first direction D1 may be referred as a first row, and the cell strings CS02 to CSN2 arranged along the first direction D1 may be referred as a second row. The cell strings CS01 and CS02 arranged along the second direction D2 may be referred as a first column, the cell strings CS11 and CS12 arranged along the second direction D2 may be referred as a second column.

Each cell string may include a ground selection transistor GST, memory cells MC1 to MC6, and string selection transistors SSTa and SSTb. The ground selection transistor GST, the memory cells MC1 to MC6, and the string selection transistors SSTa and SSTb of each cell string may be stacked in a third direction D3 perpendicular to a plane to form a three dimensional memory cell block. The plurality of cell transistors may be charge trap type transistors having different threshold voltages depending on the amount of charge trapped in an insulating layer.

The sources of the lowermost ground selection transistors GST may be commonly connected to the common source line CSL, and provides ground voltage to the cell strings.

The cell strings of different rows may be connected to different ground selection lines. For example, the gate terminals of the ground selection transistors GST of the cell strings CS01 to CSN1 in the first row may be connected to the first ground selection line GSL1, and the gate terminals of the ground selection transistors GST of the cell strings CS02 to CSN2 in the second row may be connected to the second ground selection line GSL2.

Depending on manufacturing process, the memory block BLK may include ground selection transistors which may be disposed at different heights, and the ground selection transistors at different heights may be connected to different ground selection lines.

The gate terminals of the memory cells disposed at the same height, also referred as the same order or same plane, from the substrate or the ground selection transistors GST may be commonly connected to a same word line which is one of the word lines WL1 to WL6, and the gate terminals of the memory cells disposed at different heights (or orders) may be regarded as being connected to different word lines WL1 to WL6. For example, the first memory cells MC1 are connected to the word line WL1, and the sixth memory cells MC6 are connected to the sixth word line WL6.

The lower string selection transistors SSTa of the plurality of cell strings CS01 to CSN1 and CS02 to CSN2 may be connected to the gate terminals of the lower string selection transistors SSTa. As the cell strings CS01 to CSN1 and CS02 to CSN2 are selected as a different row by selecting one of the lower string selection transistors SSTa, cell strings CS01 to CSN1 and CS02 CSN2 are connected to different string selection lines SSL1a to SSL2a respectively. For example, the lower string selection transistors SSTa of the cell strings CS01 to CSN1 of the first row are connected to the first lower string selection line SSL1a. The lower string selection transistors SSTa of the cell strings CS02 to CSN2 of the second row are commonly connected to the second lower string selection line SSL2a.

The upper string selection transistors SSTb of the plurality of cell strings CS01 to CSN1 and CS02 to CSN2 may be connected to the gate terminals of the upper string selection transistors SSTb. As the cell strings CS01 to CSN1 and CS02 to CSN2 are selected as a different row by selecting one of the upper string selection transistors SSTb, cell strings CS01 to CSN1 and CS02 CSN2 are connected to different string selection lines SSL1b to SSL2b respectively. For example, the upper string selection transistors SSTb of the cell strings CS01 to CSN1 of the first row are commonly connected to the first upper string selection line SSL1b. The second upper string selection transistors SSTb of the cell strings CS02 to CSN2 of the second row are commonly connected to the second upper string selection line SSL2b.

Because cell strings of different rows are connected to different string selection lines, each row in a word line may be selected independently and can become a page which is a unit of a single program operation. Though the example embodiment shown in FIG. 4 include both the lower string selection transistors SSTa and upper string selection transistors SSTb, the memory block may include one string selection transistor or may include more than two string selection transistors. Hereinafter, the term “string selection transistor” refers to the lower string selection transistors SSTa and/or upper string selection transistors SSTb.

Because the string selection transistors of cell strings of the same row may be commonly connected to one string selection line, each memory block receives include several string selection lines corresponding to the number of the pages the memory block includes.

Each of the plurality of cell strings CS01 to CSN1 and CS02 to CSN2 may be connected in a column direction to corresponding bit lines BL0 to BLN respectively. For example, the upper string selection transistors SSTb of the cell strings CS01 to CS02 of the first column may be commonly connected to the first bit line BL0 and may be connected to a first page buffer PB0. The upper string selection transistors SSTb of the cell strings CS11 to CS12 of the second column may be commonly connected to the bit line BL1 and may be connected to the second page buffer PB1.

Because word lines are not extended outside each block, different memory blocks may have word lines dedicated to the memory block.

As the memory cells in different planes are selected by different word lines, memory cells in different planes form a different page which is a unit of program operation or read/verify operation. For example, the cell strings CS01 to CSN1 of the first row disposed in a first plane and the cell strings CS01 to CSN1 of the second row disposed in a second plane may form different physical pages. The physical page may be a unit of a read operation and a program operation of the memory cells MC1 to MC6.

Selection of a physical page in the memory block BLK with the plurality of string selection lines SSL1a, SSL1b, SSL2a, and SSL2b is described in detail below. By applying the turn-on voltage to the first lower and upper string selection lines SSL1a and SSL1b and the turn-off voltage to the other string selection lines including the second lower and upper string selection lines SSL2a and SSL2b respectively, the cell strings CS01 to CSN1 of the first plane may be connected to the bit lines BL0 to BN. The selected memory cells of the first plane form a first physical page. By applying the turn-on voltage to the second lower and upper string selection lines SSL2a and SSL2b and the turn-off voltage to the other string selection lines including the first lower and upper string selection lines SSL1a and SSL1b, the cell strings CS02 to CSN2 of the first plane may be connected to the bit lines BL0 to BN. The selected memory cells of the first plane form a second physical page.

Physical pages may also be selected by selecting a word line among the word lines WL1 to WL6. For example, a selection voltage may be applied to the first word line WL1, and a pass voltage Vpass may be applied to the remaining word lines WL2 to WL6. The first physical page PPG1 corresponding to the first word line WL1 of the first plane may be selected by applying corresponding voltages to the string selection lines SSL1a, SSL1b, SSL2a, and SSL2b and the word lines WL1 to WL6 respectively. A read operation or a program operation may be performed on the first memory cells MC1 of the selected first physical page PPG1.

According to an embodiment, different physical pages may be simultaneously selected in the verify operation. After a program operation on the last physical page, the plurality of physical pages within a single-level cell block based on an SLC mode may be simultaneously selected in the verify operation. For simultaneous verify operation, a precharge voltage may be provided to the plurality of bit lines BL0 to BLn coupled to the plurality of physical pages.

Each memory cell MC of the memory block may store different number of data bits depending on the memory cell type and operation mode of the memory block BLK. For example, a memory block BLK may include a single level cells based on an SLC mode.

Referring to FIG. 5, the memory block BLK may include a single level cells and a program operation may be performed on the first physical page PPG1, the first memory cells MC1 of the first physical page PPG1 may have either an erased status E or a programmed status P depending on the threshold voltage Vth of the first memory cells. The first memory cells MC1 of the physical page PPG1 may store 1-bit data based on the erased status E and the programmed status P. The erased status E and the programmed status P of the first memory cells MC1 may be distinguished depending on whether the first memory cells are on-cell or off-cell in the verify operation. During the verify operation, the first memory cells MC1 having the erased status E may be regarded as on-cell, and the first memory cells MC1 having the programmed status P may be regarded as off-cell.

The memory block BLK may be a triple level cells in which 3-bit data may be stored in each of the memory cells MC of the physical page in the memory block BLK.

Each physical page may may be translated into a logical page for communicating with an external host. The translation may be performed by flash translation layer FTL typically located in the controller 100 shown in FIG. 1. The FTL may be implemented either hardware or software. For example, when the memory block BLK includes a single level memory cells based on the SLC mode, data bits written to the memory cells MC of one physical page may be translated into one logical page.

The logical page may be a unit of data accessed by the external host. When data DATA of logical pages are requested by the external host device, read operations are performed on corresponding physical pages. Each of the plurality of page buffers PB0 to PBN shown in FIG. 3 may include a data latch corresponding to the number of physical pages. However, when the number of data bits that stored in physical page are different from the number of data bits of the logical pages, the number of page buffers also may be different. For example, when the memory cell array 210 of FIG. 3 includes a triple level cell memory block, each of PB0 to PBN of FIG. 3 may include at least three data latches.

During an erase operation, the erase operation may be performed on the entire memory block regardless of the page units, thereby the memory cells MC1 to MC6 of memory blocks or sub blocks may be erased at a time. When the erase operation is performed in units of memory blocks, all memory cells MC of the memory block BLK may be simultaneously erased in response to one erase request from the controller 100. When the erase operation is performed in units of sub-blocks, some of the memory cells MC1 to MC6 of the memory block BLK may be simultaneously erased in response to one erase request from the controller 100, and the remaining other sub-blocks may be erase-inhibited. For inhibiting the erase operation in the other sub-blocks, a low voltage such as ground voltage or a low voltage close to ground voltage may be applied to a word line connected to the memory cells MC of the sub-blocks to be inhibited. The erase-inhibited memory cells MC may be in a floating state and not affected by the erase operation.

The inventive concept of the present disclosure is not limited to the embodiment shown in FIG. 4. The number of rows of cell strings may be different, thereby the number of rows of cell strings, the number of string selection lines or ground selection lines connected to the rows of cell strings and the number of cell strings connected to one bit line may be different from the numbers shown in FIG. 4.

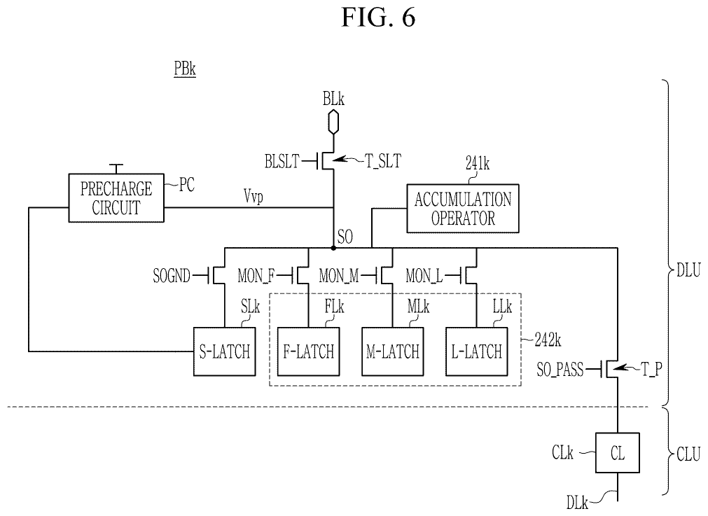

FIG. 6 illustrates a block diagram of a page buffer according to an embodiment.

Referring to FIG. 3 and FIG. 6, a k-th page buffer PBk may include a cache latch portion CLU and a data latch portion DLU. The k-th page buffer PBk may be one of a plurality of page buffers PB0 to PBN of FIG. 3. The k-th page buffer PBk may be connected to the k-th bit line BLk, and the k-th bit line BLk may be one of a plurality of bit lines BL0 to BLN of FIG. 3.

The cache latch portion CLU may include a cache latch CLk. The cache latch CLK may receive and store program data PDATA to be written into a memory cell. In addition, the cache latch CLK may store data from a sense latch SL or a data latch 242k and transmit the data to the controller 100 through a k-th data line.

The cache latch CLK may be located relatively close to output circuit of the non-volatile memory 200.

The cache latch CLk may store and latch data, also referred to as a program bit, before programming into a memory cell connected to the k-th bit line BLk during a program operation, and the stored program bit may be dumped into the sense latch SLk through the sensing node SO by the pass signal SO_PASS. The cache latch CLK may store and latch 1-bit data based on SLC mode.

The cache latch CLk may also store and latch status information indicating whether the program status for the memory block passes a verify operation. The status information may be sensed and copied from the sense latch SLk and may be dumped to the cache latch CLK through the sensing node SO by the pass signal SO_PASS.

The cache latch CLk may store and latch data sensed from the memory cell in a read or verify operation. The sensed data may be copied and dumped to the cache latch CLK through the sensing node SO by the pass signal SO_PASS.

The data latch portion DLU may include a pass transistor T_P, a sense latch SLk, an accumulation operator 241k, a data latch 242k, a precharge circuit PC, and a bit line selection transistor T_SLT.

The pass transistor T_P may be turned on or off depending on the pass signal SO_PASS. When the pass transistor T_P is turned on, data may be copied and dumped from the cache latch CLK to the sense latch SLk and/or from the cache latch CLk to the data latch 242k. The pass signal SO_PASS may be one of the page buffer control signals CTRL_P provided from the control logic 210.

The sense latch SLk may be controlled by the ground control signal SOGND in a verify operation, a read operation, a precharge operation, and a program operation of the k-th page buffer PBk. The ground control signal SOGND may be a page buffer control signal CTRL_P provided from the control logic 210.

The sense latch SLk may sense a voltage of the k-th bit line BLk during a verify operation or a read operation to store the sensed data as a sense bit. The sense latch SLk may store status information indicating whether the program status for the memory block passes by sensing the voltage level of the k-th bit line.

The sense latch SLk may also store a program bit for the program status of the memory cell connected to the k-th bit line BL in a program operation. The program bit may be dumped from the cache latch CLK to the sense latch SL through the sensing node SO by the pass signal SO_PASS.

The accumulation operator 241k may generate an accumulated bit by performing an accumulation operation on a previously accumulated bit stored in the data latch 242k and a program bit stored in the sense latch SLk or by performing an accumulation operation on a plurality of program bits stored in the data latch 242k.

The accumulation operator 241k may perform the accumulation operation by performing a bit OR operation. The accumulation operator 241k may also generate accumulated bits by performing a bit OR operation on the accumulated bits and program bits stored in the sense latch SLk. The accumulation operator 241k may generate accumulated bits by performing a plurality of bit OR operations on a plurality of program bits stored in the data latch 242k.

The accumulated bits generated by the accumulation operator 241k may be stored in the data latch 242k.

The data latch 242k may include a force latch FLk, an upper bit latch MLk, and a lower bit latch LLk. The force latch FLk, the upper bit latch MLk, and the lower bit latch LLk may be electrically connected to the sensing node SO by a transistor operating in response to various control signals MON_F, MON_M, and MON_L. The various control signals MON_F, MON_M, and MON_L may be page buffer control signals CTRL_P provided from the control logic 210.

During a program operation, at least one of the force latch FLk, the upper bit latch MLk, and the lower bit latch LLk may store an accumulated bit generated from the accumulation operator 241k or a program bit programmed into a memory cell connected to the k-th bit line BLk.

The accumulated bit stored in at least one of the force latch FLk, the upper bit latch MLk, and the lower bit latch LLk may be provided to the accumulation operator 241k. Thereafter, the accumulated bit generated by the accumulation operator 241k may be stored in at least one of the force latch FLk, the upper bit latch MLk, and the lower bit latch LLk.

While continuing accumulation of data stored in the data latch 242k, the program bits stored in the force latch FLk, the upper bit latch MLk, and the lower bit latch LLk may be provided to the accumulation operator 241k.

When the memory cell connected to the k-th bit line BLk is TLC, the force latch FLk may generally be utilized to improve the threshold voltage distribution during the program operation. In addition, the upper bit latch MLk, the lower bit latch LLk, and the cache latch CLK may be utilized to store program data PDATA from the the controller 100. Program bits stored in the upper bit latch MLk, the lower bit latch LLk, and the cache latch CLK may correspond to a target program status to be programmed in the memory cell. For example, the cache latch CLK may store an upper bit for a program status of a memory cell connected to the k-th bit line BLk in the program operation. The upper bit may be dumped into the sense latch SL through the sensing node SO by the pass signal SO_PASS. The upper bit latch MLk may store a middle bit for a program status of a memory cell connected to the k-th bit line BLk. The middle bit may be dumped into the sense latch SLk through the sensing node SO by the upper bit latch control signal MON_M. The lower bit latch LLk may store the lower bit for the program status of the memory cell connected to the k-th bit line BLk. The lower bit may be dumped into the sense latch SL through the sensing node SO by the lower bit latch control signal MON_L.

The precharge circuit PC may provide a specific level of precharge voltage Vvp to the k-th bit line BLk during the read operation or the verify operation in response to the page buffer control signal CTRL_P.

The precharge circuit PC may provide the precharge voltage Vvp to the k-th bit line BLk based on the accumulated bit in the verify operation in response to the page buffer control signal CTRL_P. For example, when the stored accumulated bit or the accumulated bit generated by the accumulation operator 241k is logic low, the precharge circuit PC may provide the precharge voltage Vvp to the k-th bit line BLk in the verify operation.

The precharge circuit PC may perform the verify operation after performing several program operations in response to the page buffer control signal CTRL_P. For example, the precharge circuit PC may perform the verify operation based on a number of program operations on the memory block after an erase operation on the memory block connected to the k-th bit line BLk.

The sensing node SO may be precharged during the program operation, the verify operation, the read operation, or the erase operation for the non-volatile memory device 200. For example, the sensing node SO may be connected to the k-th bit line BLk through a bit line selection transistor T_SLT. The bit line selection transistor T_SLT may be turned on or off depending on the bit line selection signal BLSLT. The bit line selection transistor T_SLT may be an NMOS transistor and may be implemented as a high-voltage transistor, but is not limited thereto.

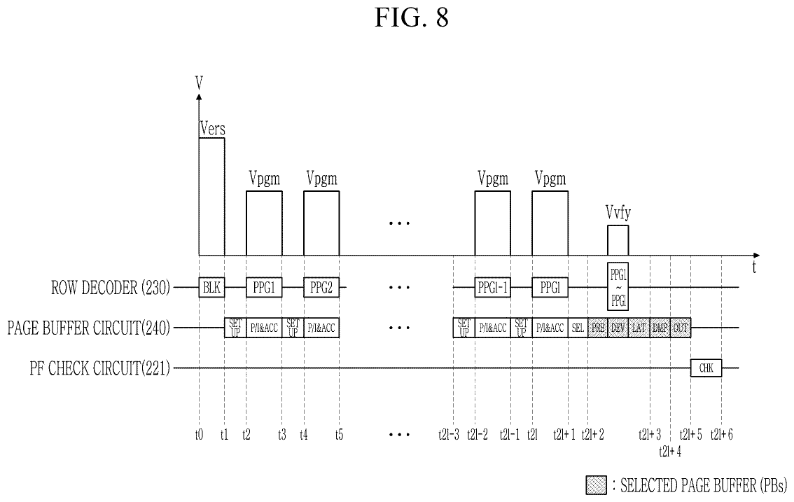

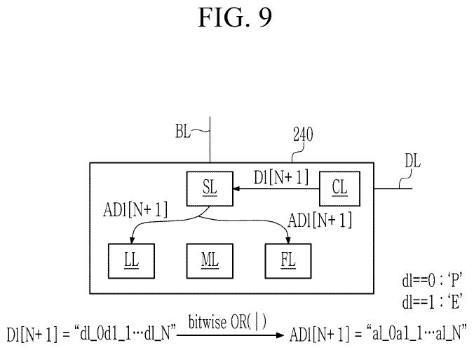

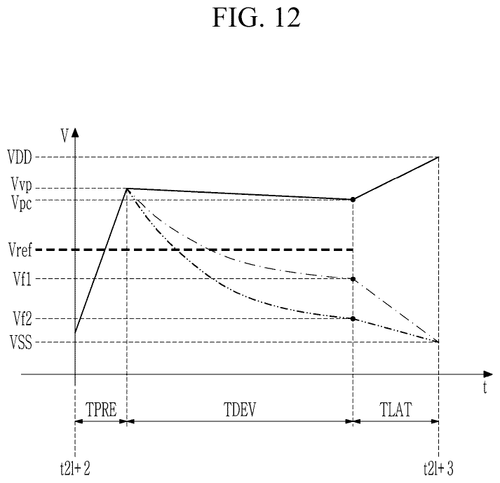

FIG. 7 illustrates a flowchart of an operation method of a non-volatile memory device according to an embodiment. FIG. 8 illustrates a timing diagram of an operation method of a non-volatile memory device according to an embodiment. FIG. 9 to FIG. 12 are drawings for describing an operating method of a non-volatile memory device according to an embodiment. Specifically, FIG. 12 illustrates a voltage of a bit line in a verify operation.

Referring to FIG. 1, FIG. 3, FIG. 6, FIG. 7, and FIG. 8, the non-volatile memory device 200 performs the erase operation on the memory block BLK that is one of a plurality of single-level cell memory blocks BLKS1 to BLKSx (S105).

The row decoder 230 selects the memory block BLK, and the erase voltage Vers is provided to the memory block BLK through the common source line CSL so that the erase operation may be performed during time between t0 and t1.

Because the memory cells of the non-volatile memory device 200 may not be overwritten, the erase operation may be performed before performing the program operation on the memory cell in the memory block BLK.

Referring to FIG. 7, the SLC program of the non-volatile memory device 200 may be initiated by receiving an SLC program command CMD_SP for the memory block BLK (S110).

The non-volatile memory device 200 may receive the program data PDATA, the address ADDR which indicates the location of memory cell for the program data PDATA to be written together with the SLC program command CMD_SP from the controller 100. Though the program operation on the memory block BLK based on the SLC program command CMD_SP is described, the program operation may also be applied to a multi-level cell memory or a random access memory.

The SLC program command CMD_SP may initiate the program operation based on the SLC mode in which the memory block BLK may be a triple-level cell memory block.

Upon receiving the program data PDATA, the page buffer circuit 240 sets up data for a physical page (S115) during time between t1 and t2.

The page buffer circuit 240 may set up the program data PDATA of the first physical page PPG1 by loading the program data PDATA into a plurality of sense latches.

Referring to FIG. 9, the page buffer circuit 240 may receive the first data D1 for the SLC program command CMD_SP from the plurality of data lines DL. The first data D1 may be copied to a plurality of sense latches SL through a plurality of cache latches CL.

The first data D1 may include program bits dl_0 to dl_N corresponding to a plurality of bit lines BL of a plurality of page buffers PB0 to PBN. Each of the program bits dl_0 to dl_N may correspond to status of a memory cell connected to each of the plurality of bit lines BL during the program operation. For example, when the program bit dl_0 is a logic high ‘1’, the memory cell connected to the first bit line of the first page buffer PB0 during the program operation may be in the erased status E. Alternatively, when the program bit dl_0 is a logic low ‘0’, the memory cell connected to the first bit line of the first page buffer PB0 during the program operation may be in the programmed status P.

Upon setting up the program data PDATA into the sense latches, a first program operation may be performed on the first physical page and the page buffer circuit 240 performs the data accumulation operation in units of physical pages (S120) during time between t2 and t3.

The accumulation operator of the page buffer circuit 240 may perform the data accumulation operation by accumulating data stored in one of the data latches and the first data D1 set up in the plurality of sense latches SL. The accumulation operator may perform a bit OR operation for accumulating data stored in one of the data latches and the first data D1, and generate the first accumulated data AD1.

Since there is no accumulated data before the setup of the first data D1, the first accumulated data AD1 may be the same as the first data D1. Each of the program bits dl_0 to dl_N of the first data D1 may be the same as each of the accumulated bits a1_0 to a1_N of the first accumulated data AD1.

The first accumulated data AD1 may be stored in a plurality of lower bit latches LL and a plurality of force latches FL, and may be copied to the accumulation operator of the page buffer circuit 240.

The second program operation may be performed by applying the program voltage to the second physical page (S125) during time between t4 and t5, and the first accumulated data AD1 are accumulated with the second data D2 and output a second accumulated data AD2.

In conjunction with the accumulation operation of the page buffer circuit 240, during time between t2 and t3 and time between t4 and t5, the row decoder 230 may provide the program voltage Vpgm to the first physical page PPG1 and the second physical page PPG2 respectively by controlling the voltages of the string selection lines SSL, the ground selection line GSL, and the selected word line WL within the memory block BLK.

While the program voltage Vpgm is applied to the selected word lines, the inhibit voltage is applied to other unselected word lines. The page buffer circuit 240 may selectively provide the connected bit line with corresponding program voltage or corresponding inhibit voltage. The program operation continues till applying the program voltage to the last physical page PPGN of the selected word line, and the accumulator circuit of the page buffer accumulates the previously accumulated data ADN-1 with the data DN programmed into the last physical page PPGN, and output the last accumulated data ADl.

Though the Step S120 and step S125 are separately illustrated in FIG. 7, the step S120 and step S125 may be performed simultaneously in time.

In the Step S130, the page buffer circuit 240 checks whether the programmed physical page is the last page (S130).

In the present disclosure, the “last page” may refer to the last physical page of the selected word line.

For example, the page buffer circuit 240 may check the last page when the program operation is performed on the last physical page of the selected word line. The page buffer circuit 240 may check the last page based on the number of the physical pages programmed in the memory block BLK after the erase operation of step S105.

When the page buffer circuit 240 does not determine that the programmed physical page is the last page, the non-volatile memory device 200 may repeat the Step S110 to the Step S130 during time between t3 and t2l+1.

During time between t3 and t2l+1, the non-volatile memory device 200 may perform program operation on the second physical pages PPG2 to the last physical page PPGl.

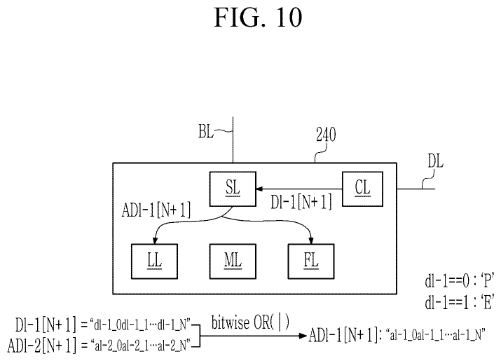

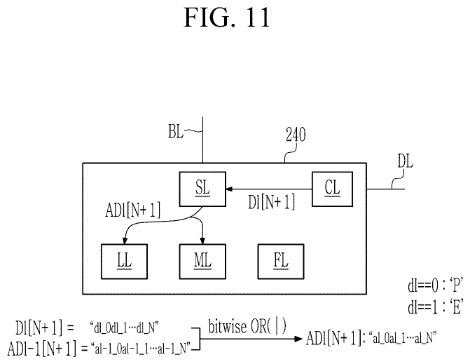

Referring to FIG. 10 and FIG. 11, the page buffer circuit 240 may receive the data Dl-1 for the physical page PPGl-1 from a plurality of data lines DL during time between t2l−3 and t2l−2. The data Dl-1 may be copied to a plurality of sense latches SL through a plurality of cache latches CL.

The data DL-1 may include program bits dl-1_0 to dl-1_N which correspond to a plurality of bit lines BL of a plurality of page buffers PB0 to PBN respectively. Each of the program bits dl-1_0 to dl-1_N may correspond to a status of a memory cell connected to each of the plurality of bit lines BL after performing the program operation. For example, when the program bit dl-1_0 is a logic high ‘1’, the memory cell connected to the first bit line of the first page buffer PB0 after the program operation may be in an erased status E. Alternatively, when the program bit dl-1_0 is a logic low ‘0’, the memory cell connected to the 0-th bit line of the 0-th page buffer PB0 after the program operation may be in a programmed status P.

The accumulation operator of the page buffer circuit 240 may perform a data accumulation operation based on the accumulated data ADl-2 stored in the plurality of lower bit latches LL and the data Dl-1 set up in the plurality of sense latches SL during time between t2l−2 and t2l−1. The accumulation operator may perform a bit OR operation on the accumulated data ADl-2 and the data DL-1 to generate the accumulated data ADl-1.

Each of the accumulated bits al-1_0 to al-1_N of the accumulated data ADl-1 may be a result of the bit OR operation with respect to the accumulated bits al-2_0 to al-2_N of the accumulated data ADl-2 and with respect to the program bits dl-1_0 to dl-1_N of the data Dl-1.

The accumulated data ADl-1 may be stored in the plurality of lower bit latches LL and the plurality of force latches FL, and then copied and provided to the accumulation operator of the page buffer circuit 240.

The page buffer circuit 240 may receive the last data Dl for the last physical page PPGl from the plurality of data lines DL during time between t2l−1 and t2l. The last data Dl may be copied to the plurality of sense latches SL through the plurality of cache latches CL and set up for the next accumulation operation.

The last data Dl may include program bits dl_0 to dl_N which correspond to the plurality of bit lines BL of the plurality of page buffers PB0 to PBN. Each of the program bits dl_0 to dl_N may correspond to a status of a memory cell connected to each of the plurality of bit lines BL after performing the program operation. For example, when the program bit dl_0 is a logic high ‘1’, the memory cell connected to the first bit line of the first page buffer PB0 after the program operation may be in an erased status E. Alternatively, when the program bit dl_0 is a logic low ‘0’, the memory cell connected to the first bit line of the first page buffer PB0 after the program operation may be in a programmed status P.

The accumulation operator of the page buffer circuit 240 may perform a data accumulation operation based on the accumulated data ADl-1 stored in the plurality of lower bit latches LL and the last data Dl set up for the next accumulation operation in the plurality of sense latches SL during time between t2l and t2l+1. The accumulation operator may perform a bit OR operation on the accumulated data ADl-1 and the lastdata DL to generate the last accumulated data ADl.

Each of the accumulated bits al_0 to al_N of the last accumulated data ADl may be a result of bit OR operation with respect to the accumulated bits al-1_0 to al-1_N of the accumulated data ADl-1 and the program bits dl_0 to dl_N of the data Dl.

The last accumulated data ADl may be stored in a plurality of lower bit latches LL and a plurality of upper bit latches ML. Through the accumulation operation of the page buffer circuit 240, the plurality of lower bit latches LL and the plurality of upper bit latches ML may store the last accumulated data ADl, and the plurality of force latches FL may store the accumulated data ADl-1.

When the page buffer circuit 240 determines that the programmed physical page is the last page, the page buffer circuit 240 selects the accumulated bits al_0 to al_N of the last accumulated data ADl as final accumulated bit for the next step which is a verification operation (S135).

Each of the accumulated bits al_0 to al_N of the last accumulated data ADl may indicate the status of a memory cell connected to a bit line corresponding to the plurality of page buffers PB0 to PBN. For example, the status of the accumulated bit al_0 is a logic low ‘0’ when the bit is in a programmed status, which indicates that the status of all memory cells connected to the first page buffer PB0 within the first to the last physical pages PPG1 to PPGl is in a programmed status.

The page buffer circuit 240 may select a page buffer in which the status of all connected memory cells is a programmed status by checking the accumulated bits al_0 to al_N of the last accumulated data ADl during time between t2l+1 and t2l+2. The page buffer circuit 240 may select a page buffer among a plurality of page buffers PB0 to PBN as a selected page buffer PBs in which an last accumulated data ADl are stored.

If the values of the accumulated bits al_0 to al_N of the last accumulated data ADl are all logic level ‘1’, the page buffer circuit 240 may check the accumulated bits al-1_0 to al-1_N of the accumulated data ADl-1 to select a page buffer corresponding to an accumulated bit having a logic level ‘0’.

During the verification operation, the page buffer circuit 240 simultaneously verifies memory cells connected to the selected page buffer PBs (S140).

The selected page buffer PBs may provide a precharge voltage Vvp of a specific level to the bit line during the precharge period and sense the voltage of the bit line after the development period to latch the status information during time between t2l+2 and t2l+3.

Referring to FIG. 12, the selected page buffer PBs may provide the precharge voltage Vvp to the connected bit line during the precharge period TPRE.

During the development period TDEV, the row decoder 230 may select the first to last physical pages PPG1 to PPGl by controlling the voltages of the string selection line SSL, the ground selection line GSL, and the word line WL within the memory block BLK and provide a verify voltage Vvfy.

During the verification operation, the row decoder 230 may simultaneously select a plurality of string selection lines SSL within the memory block BLK and simultaneously provide the verify voltage (Vvfy) to the plurality of word lines WL. Because the plurality of string selection lines SSL within the memory BLK are selected simultaneously, all of the physical pages coupled to the plurality of string selection lines SSL are sensed together, and the sensed data are merged in the bit line BL. The merging of the sensed data in the bit line BL during the verification operation may correspond to the accumulation of the program data during the program operation.

The selected page buffer PBs may simultaneously determine whether a plurality of memory cells connected to the selected page buffer PBs are off-cells through the operation of the row decoder 230.

If all of the plurality of memory cells of the first to the last physical pages PPG1 to PPGl connected to the selected page buffer PBs are in a programmed status, the voltage of the bit line may be in the pass check voltage Vpc because the plurality of memory cells are off-cells after the development period TDEV which indicates all of the plurality of the memory cells are programmed properly.

If some of the plurality of memory cells of the first to the last physical pages PPG1 to PPGl connected to the selected page buffer PBs are in an erased status, the voltage of the bit line may be in a first fail voltage Vf1 due to some on-cells among the plurality of memory cells after the development period TDEV which indicates some of the plurality of the memory cells are not programmed properly.

If all of the plurality of memory cells of the first to the last physical pages PPG1 to PPGl connected to the selected page buffer PBs are in an erased status, all of the plurality of memory cells may be on-cells after the development period TDEV, and the voltage of the bit line may be in a second fail voltage Vf2 which indicates the plurality of the memory cells are not programmed at all.

The pass check voltage Vpc may be higher than the reference voltage Vref, and the first and second fail voltages Vf1 and Vf2 may be lower than the reference voltage Vref.

During the latch period TLAT, the sense latch of the selected page buffer PBs may detect and latch the voltage of the bit line based on the reference voltage Vref. If the voltage of the bit line after the development period TDEV is higher than the reference voltage Vref, the selected page buffer PBs may latch a first voltage level which may be the first power voltage VDD during the latch period TLAT to store the status information. If the voltage of the bit line after the development period TDEV is lower than the reference voltage Vref, the selected page buffer PBs may latch a second voltage level which may be the second power voltage VSS during the latch period TLAT to store the status information.

The stored status information may indicate whether the program operation is successfully performed on the memory block BLK. The status information of the first power voltage VDD may indicate the program pass for the memory block BLK, and the status information of the second power voltage VSS may indicate the program fail for the memory block BLK.

The pass/fail check circuits 221 checks the PSF information based on the latched status information (S145).

The latched status information may be copied to the cache latch CL during time between t2l+3 and t2l+4. The status information copied to the cache latch CL may be transmitted to the pass/fail check circuits 221 during time between t2l+4 and t2l+5.

The pass/fail check circuits 221 may check the latched status information to generate PSF information for the memory block BLK during time between t2l+5 and t2l+6. Thereafter, the non-volatile memory device 200 may transmit the PSF information for the memory block BLK to the controller 100 in response to the program status check command CMD_PSF from the controller 100.

In FIG. 8, it is illustrated that a plurality of program operations are performed in sequential access manner, but it is not limited thereto, and the verify operation of the present disclosure may be applied even if there is a time interval between the program operations.

The non-volatile memory device 200 may improve the overall program operation speed by replacing a plurality of verify operations performed for each program operation with one verify operation by accumulating data to be written into the memory cell block BLK. The reliability of the program operation may also be preserved.

The non-volatile memory device 200 may perform a verify operation by accumulating data regardless of the limited number of data latches by performing a data accumulation operation for each program operation. According to an embodiment, when the program operation is determined to be a fail and the program status information sent to the controller 100 indicates the program operation failed, the controller 100 may perform further steps to track down the physical page among the plurality of physical pages on which the program operation is performed. For tracking down the failed physical page, the controller 100 may perform a second verify operation excepting the last physical page. The accumulated data ADl-1 instead of ADl may be used for the second verify operation, and all string selection lines excepting the string selection line for the last physical page are selected for the second verify operation. If the second verification operation is determined to be successful, which indicates that the last physical page include fail memory cells. Otherwise, one of the physical pages among the physical pages on which the second verification performed still include fail memory. By repeating the steps excluding the latter physical page and performing another verification operation, the defective physical page including memory cells not properly programmed may be tracked down.

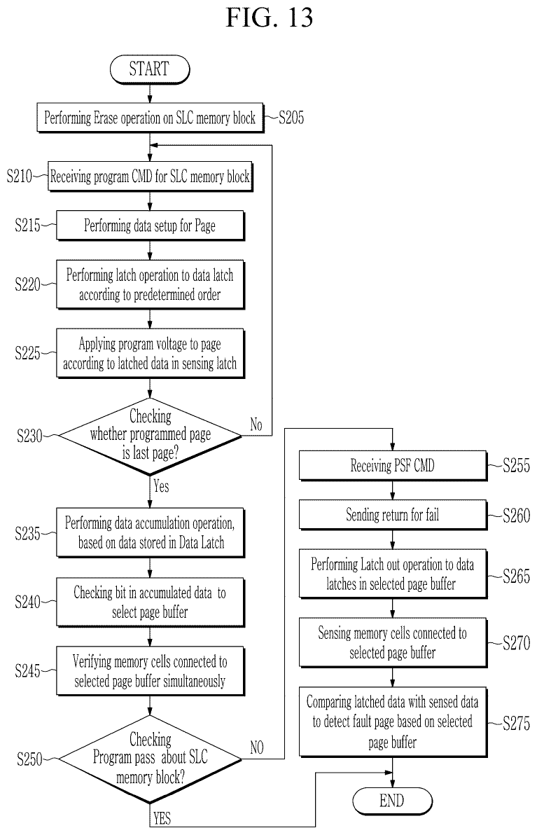

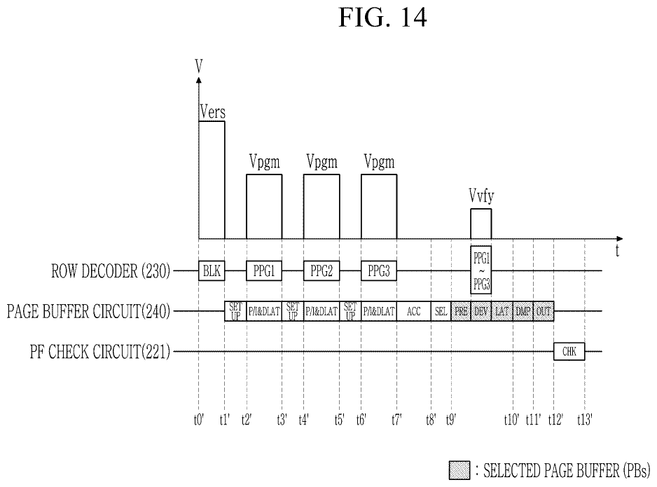

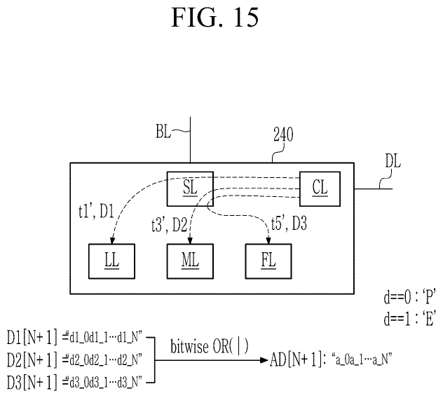

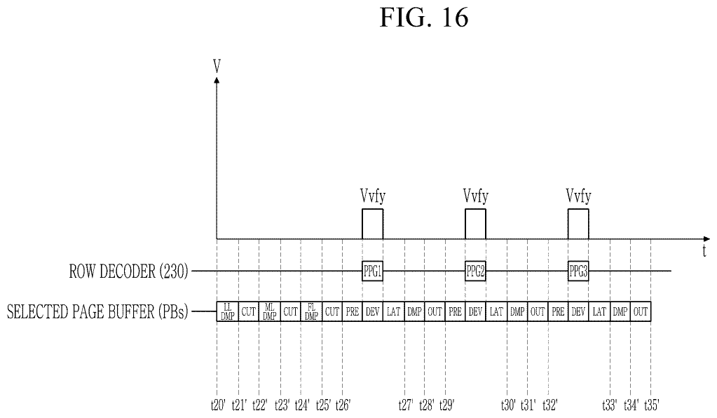

FIG. 13 illustrates a flowchart of an operation method of a non-volatile memory device according to an embodiment. FIG. 14 illustrates a timing diagram of an operation method of a non-volatile memory device according to an embodiment. FIG. 15 is a drawing for describing an operating method of a non-volatile memory device according to an embodiment. FIG. 16 illustrates a timing diagram of an operation method of a non-volatile memory device according to an embodiment.

Referring to FIG. 1, FIG. 3, FIG. 6, FIG. 13, and FIG. 14, the non-volatile memory device 200 performs an erase operation on a memory block BLK that is one of a plurality of single-level cell SLC memory blocks BLKS1 to BLKSx (S205).

Step S205 is performed as described in step S105 of FIG. 7.

The row decoder 230 selects the memory block BLK for the erase operation, and the erase voltage Vers is applied to the memory block BLK through the common source line CSL during time between to′ and t1′.

The non-volatile memory device 200 receives the SLC program command CMD_SP for the memory block BLK (S210).

Step S210 is performed as described in step S110 of FIG. 7.

The page buffer circuit 240 sets up data for a physical page (S215).

Step S215 is performed as described in step S115 of FIG. 7.

The page buffer circuit 240 may set up data programmed to the first physical page PPG1 in the memory block BLK in a plurality of sense latches during time between t1′ and t2′.

Referring to FIG. 15, the page buffer circuit 240 may receive the first data D1 for the SLC program command CMD_SP from the plurality of data lines DL. The first data D1 may be copied to a plurality of sense latches SL through a plurality of cache latches CL and set up data for the program operation. The first data D1 may include the program bits dl_0 to dl_N corresponding to a plurality of bit lines BL of a plurality of page buffers PB0 to PBN.

The page buffer circuit 240 performs a latch operation on data set up in the data latch according to a predetermined order (S220).

The first data D1 set up in the plurality of sense latches SL may be copied into the plurality of lower bit latches LL during time between t2′ and t3′.

The non-volatile memory device 200 provides a program voltage to the physical page to perform the program operation on the memory cell of the physical page (S225).

Step S225 is performed as described in step S125 of FIG. 7.

In conjunction with the latch operation of the page buffer circuit 240, the row decoder 230 may provide the program voltage Vpgm to the first physical page PPG1 by controlling the voltages of the string selection line SSL, the ground selection line GSL, and the word line WL within the memory block BLK during time between t2′ and t3′.

The page buffer circuit 240 checks whether the programmed physical page is the last page (S230).

Step S230 is performed as described in step S130 of FIG. 7.

The page buffer circuit 240 may compare the number of program operations performed in the memory block BLK after an erase operation with the number of data latches included in one page buffer. For example, the data latch 242k of the k-th page buffer PBk shown in FIG. 6 includes a force latch FLk, an upper bit latch MLk, and a lower bit latch LLk, thereby the reference number of times for the checking operation of step S230 may be three.

Until the page buffer circuit 240 determining that the programmed physical page is the last page, the non-volatile memory device 200 may repeat step S210 to step S230.

The non-volatile memory device 200 may repeat step S210 to step S230 for the second to first physical pages PPG2 to PPG1 during time between t3′ and t7′.

The page buffer circuit 240 may receive the second data D2 for the second physical page PPG2 from the plurality of data lines DL during time between t3′ and t7′. The second data D2 may be copied to a plurality of sense latches SL through a plurality of cache latches CL and set up for the second program operation.

The second data D2 may include the program bits d2_0 to d2_N corresponding to a plurality of bit lines BL of a plurality of page buffers PB0 to PBN. Each of the program bits d2_0 to d2_N may correspond to a status of a memory cell connected to each of the plurality of bit lines BL after performing the second program operation. The second data D2 may be stored in the plurality of upper bit latches ML.

The page buffer circuit 240 may receive the third data D3 for the third physical page PPG3 from the plurality of data lines DL during time between t5′ and t6′. The third data D3 may be copied to a plurality of sense latches SL through the plurality of cache latches CL and set up for third program operation.

The third data D3 may include the program bits d3_0 to d3_N corresponding to a plurality of bit lines BL of a plurality of page buffers PB0 to PBN. Each of the program bits d3_0 to d3_N may correspond to a status of a memory cell connected to each of the plurality of bit lines BL after performing the third program operation. The third data D3 may be stored in a plurality of force latches FL.

The page buffer circuit 240 performs a data accumulation operation based on data stored in the data latch (S230).

The accumulation operator of the page buffer circuit 240 may perform a data accumulation operation based on the first to third data D1 to D3 stored in each of the plurality of lower bit latches LL, the plurality of upper bit latches ML, and the plurality of force latches FL during time between t7′ and t8′. The accumulation operator may perform a bit OR operation on the first to third data D1 to D3 to generate the accumulated data AD.

Each of the accumulated bits a_0 to a_N of the accumulated data AD may be a result from bit OR operation on each of program bits dl_0 to dl_N of the first data D1, each of the program bits d2_0 to d2_N of the second data D2, and each of the program bits dl_0 to dl_N of the third data D3. For example, the first accumulated bit a_0 may be a result from bit OR operation on the program bit dl_0, the program bit d2_0, and the program bit d3_0.

When the page buffer circuit 240 determines that the programmed physical page is the last page, the page buffer circuit 240 selects the physical page corresponding to the accumulated bit of the accumulated data as the last page.

Step S240 is performed as described in S135 of FIG. 7.

Each of the accumulated bits a_0 to a_N of the accumulated data AD may indicate the status of a memory cell connected to a bit line of a corresponding plurality of page buffers PB0 to PBN. For example, when the program bit is a logic low ‘0’, the status of all memory cells connected to the first page buffer PB0 within the first to third physical pages PPG1 to PPG3 is in a programmed status.

The page buffer circuit 240 may select a page buffer in which the status of all connected memory cells is in a programmed status by checking the accumulated bits al_0 to al_N of the accumulated data AD during time between t8′ and t9′.

The page buffer circuit 240 simultaneously verifies memory cells connected to the selected page buffers PBs (S245).

Step S245 is performed as described in step S140 of FIG. 7.

The selected page buffer PBs may provide a precharge voltage Vvp of a specific level to the bit line in the precharge period and sense the voltage of the bit line after the development period to latch the status information during time between t9′ and t10′.

During the development period, the row decoder 230 may select the first to third physical pages PPG1 to PPG3 by controlling the voltages of the string selection line SSL, the ground selection line GSL, and the word line WL within the memory block BLK and provide a verify voltage Vvfy.

The pass/fail check circuits 221 checks the PSF information based on the latched status information (S250).

Step S250 is performed as described in S145 of FIG. 7.

The latched status information may be copied to the cache latch CL, and may be transmitted to the pass/fail check circuits 221 during time between t10′ and t11′.

The pass/fail check circuits 221 may check the latched status information to generate PSF information for the memory block BLK during time between t12′ and t13′.

The controller 100 may transmit the PSF information for the memory block BLK to the non-volatile memory device 200 to check whether the program operation on the memory block BLK has failed. Upon receiving a program status check command CMD_PSF for the memory block BLK (S265), the non-volatile memory device 200 may transmit the PSF information for the memory block BLK to the controller 100.

When the PSF information for the memory block BLK indicates a program fail, the non-volatile memory may perform further program operation on the memory block BLK.

In the step S265, the page buffer circuit 240 performs a latch out operation for the data latch in the selected page buffer PBs.

Referring to FIG. 16, the program bit stored in the lower bit latch LL in the selected page buffer PBs among the program bits dl_0 to dl_N of the first data D1 may be copied into the cache latch CL, and may be transmitted to the pass/fail check circuit 221 during time between t20′ and t2l′.

The program bit stored in the upper bit latch ML in the selected page buffer PBs among the program bits d2_0 to d2_N of the second data D2 may be copied into the cache latch ML, and may be transmitted to the pass/fail check circuit 221 during time between t22′ and t23′.

The program bit stored in the force latch FL in the selected page buffer PBs among the program bits d3_0 to d3_N of the third data D3 may be copied into the cache latch ML, and may be transmitted to the pass/fail check circuit 221 during time between t24′ and t25′.

The page buffer circuit 240 performs a sensing operation on the memory cell connected to the selected page buffer PBs (S265).

The selected page buffer PBs may provide a precharge voltage Vvp of a specific level to the bit line during the precharge period and sense the voltage of the bit line after the development period to latch the data stored in the memory cell during time between t26′ and t27′.

During the development period, the row decoder 230 may select the first physical page PPG1 by controlling the voltages of the string selection line SSL, the ground selection line GSL, and the word line WL within the memory block BLK and provide a verify voltage Vvfy on the word line.

The selected page buffer PBs may determine whether the memory cell of the first physical page PPG1 connected to the selected page buffer PBs is an off-cell or on-cell after the verify operation. During the latch period, the sense latch of the selected page buffer PBs may sense the voltage of the bit line to detect whether the memory cell of the first physical page PPG1 is an off-cell or on-cell.

The latched data may be copied into the cache latch CL and may be transmitted to the pass/fail check circuit 221 during time between t27′ and t28′.

The selected page buffer PBs may provide a precharge voltage Vvp of a specific level to the bit line during the precharge period and sense the voltage of the bit line after the development period to latch the data stored in the memory cell during time between t29′ and t30′.

During the development period, the row decoder 230 may select the second physical page PPG2 by controlling the voltages of the string selection line SSL, the ground selection line GSL, and the word line WL within the memory block BLK and may provide a verify voltage Vvfy on the word line WL.

The selected page buffer PBs may determine whether the memory cell of the second physical page PPG2 connected to the selected page buffer PBs is an off-cell or on-cell after the verify operation. The sense latch of the selected page buffer PBs may sense the voltage of the bit line to determine whether the memory cell of the second physical page PPG2 is an off-cell or on-cell.

The latched data may be copied into the cache latch CL, and may be transmitted to the pass/fail check circuit 221 during time between t30′ and t31′.

The selected page buffer PBs may provide a precharge voltage Vvp of a specific level to the bit line during the precharge period and sense the voltage of the bit line after the development period to latch the data stored in the memory cell during time between 32′ and t33′.

During the development period time between t33′ and t34′, the row decoder 230 may select the third physical page PPG3 by controlling the voltages of the string selection line SSL, the ground selection line GSL, and the word line WL within the memory block BLK and may provide a verify voltage Vvfy on the word line WL.

The selected page buffer PBs may determine whether the memory cell of the third physical page PPG3 connected to the selected page buffer PBs is an off-cell or on-cell after the verify operation. The sense latch of the selected page buffer PBs may sense the voltage of the bit line to determine whether the memory cell of the third physical page PPG3 is an off-cell or on-cell.

The latched data may be copied into the cache latch CL, and may be transmitted to the pass/fail check circuit 221 during time between t33′ and t34′.

The pass/fail check circuit 221 compares data latched in the data latch in the selected page buffer PBs with data sensed in the selected page buffer PBs to detect a fault page (S275).

The pass/fail check circuit 221 may detect a fault page among the first to third physical pages PPG1 to PPG3 by comparing the data latched out from the data latch during time between t20′ and t35′ with the sensed data. The pass/fail check circuit 221 may determine a physical page as a fault page in which the latched out data and corresponding sensed data are different from each other.

The information on the fault page may be provided to the controller 100 as a return signal in response to the program status check command CMD_PSF.

The non-volatile memory device 200 may improve the overall program operation speed by replacing a plurality of verify operations performed for each program operation with one verify operation by accumulating each program data of the physical pages on which program operation are performed.

The non-volatile memory device 200 may further perform a additional verification operation to detect a fault page when the PSF information for a memory block BLK indicates that the memory block BLK includes a memory cell which is not properly programmed during the program operation. According to an embodiment, when the program operation has not been successful and the program status information sent to the controller 100 indicates the program operation failed, the controller 100 may perform further steps to track down the physical page among the plurality of physical pages on which the program operation is performed. For tracking down the failed physical page, the controller 100 perform a second verification excepting the last physical page. The accumulated data ADl-1 instead of ADl may be used, and all string selection lines excepting the string selection line for the last physical page are selected for the verification operation. If the second verification operation has been successful, which indicates that the last physical page include a fault memory cell, otherwise, one of the physical pages among the physical pages on which the second verification performed still includes a fault memory cell that is not programmed properly during the program operation. By repeating those steps excluding the latter physical page and performing another verification operation, the physical page including the fault memory cell may be tracked down. The storage device 10 may detect and store a fault page in the non-volatile memory device 200 without separate buffer memory for storing information relating with the fault page.

When performing a program operation on a memory block operating as an SLC such as an SLC mode or SLC caching, the non-volatile memory device 200 may improve speed of the program operation.

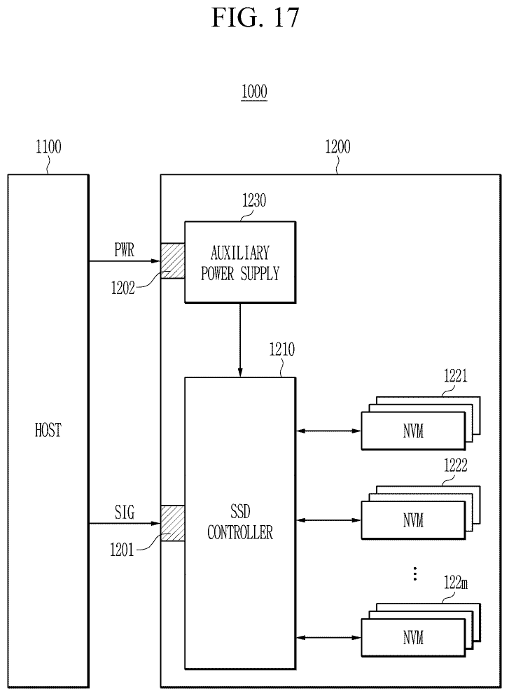

FIG. 17 illustrates a block diagram of an SSD system to which a storage device according to an embodiment is applied. Referring to FIG. 17, an SSD system 1000 includes a host 1100 and an SSD 1200.

The SSD 1200 may exchange signals SIG with the host 1100 through a signal connector 1201 and receive power PWR through a power connector 1202. The SSD 1200 may include an SSD controller 1210, a plurality of flash memories 1221 to 122m, and an auxiliary power supply 1230. The plurality of flash memories 1221 to 122m may be connected to the SSD controller 1210 through a plurality of channels respectively. In some embodiments, the SSD 1200 may be a DRAMless storage device which does not require a separate buffer memory for storing program failure information.

The SSD controller 1210 may control the plurality of flash memories 1221 to 122m in response to the signal SIG received from the host 1100. The SSD controller 1210 may correspond to the controller 100 in FIG. 1 to FIG. 16. The SSD controller 1210 may provide commands, such as an SLC program command, a program status check command, and a command for data latch out to the plurality of flash memories 1221 to 122m.

The plurality of flash memories 1221 to 122m may operate under the control of the SSD controller 1210. The flash memories 1221 to 122m may operate as the non-volatile memory device 200 in FIG. 1 to FIG. 16. When the flash memories 1221 to 122m performs a program operation on a memory block operating as a single level cell SLC such as an SLC mode or SLC caching, it may perform a verify operation with respect to a plurality of program operations based on accumulated data to ensure speed performance and reliability.

The auxiliary power supply 1230 is connected to the host 1100 through the power connector 1202.

The auxiliary power supply 1230 may be connected to the host 1100 through the power connector 1202. The auxiliary power supply 1230 may receive the power PWR from the host 1100. When the power supply from the host 1100 is not stable, the auxiliary power supply 1230 may provide power to the SSD 1200.

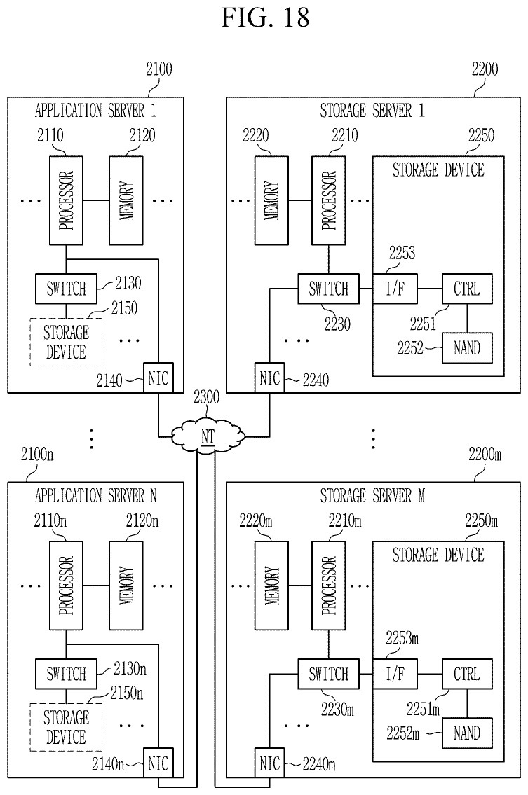

FIG. 18 illustrates a block diagram of a data center to which a storage device according to an embodiment is applied. Referring to FIG. 18, a network system 2000 is a facility that collects various data and provides services and may be referred to as a data center or a data storage center. The network system 2000 may include application servers 2100 to 2100n and storage servers 2200 to 2200m, and the application servers 2100 to 2100n and the storage servers 2200 to 2200m may be referred to as computing nodes. The number of the application servers 2100 to 2100n and the number of the storage servers 2200 to 2200m may be different from each other.

The application servers 2100 to 2100n and the storage servers 2200 to 2200m may communicate with each other through a network 2300. The network 2300 may be implemented using a fiber channel (FC) or Ethernet. In this case, the FC is a medium used for high-speed data transmission, and an optical switch providing high performance/high availability may be used. Depending on the access method of the network 2300, the storage servers 2200 to 2200m may be provided as file storage, block storage, or object storage.

The network 2300 may be a storage-only network, such as a storage area network (SAN). For example, the SAN may be an FC-SAN that uses an FC network and is implemented according to FC protocol (FCP). The SAN may be an IP-SAN that uses a TCP/IP network and is implemented according to an iSCSI (SCSI over TCP/IP or Internet SCSI) protocol. The network 2300 may be a general network such as a TCP/IP network. For example, the network 2300 may be implemented according to a protocol such as FC over Ethernet (FCOE), Network Attached Storage (NAS), and NVMe over Fabrics (NVMe-oF).

The application server 2100 may include a processor 2110 and a memory 2120. The processor 2110 may control the overall operation of the application server 2100, and may access the memory 2120 to execute instructions and/or data loaded in the memory 2120. The number of the processors 2110 and the number of the memories 2120 included in the application server 2100 may be different depending on the applications. The processor 2110 and the memory 2120 may be configured as a processor-memory pair. The number of the processors 2110 and the number of the memories 2120 may be different from each other.

The application server 2100 may further include a storage device 2150. The number of the storage devices 2150 included in the application server 2100 may be different depending on the applications. The processor 2110 may provide a command to the storage device 2150, and the storage device 2150 may operate in response to the command received from the processor 2110. The present disclosure is not limited thereto, and the application server 2100 may not include the storage device 2150.

The application server 2100 may further include a switch 2130 and a network interface card (NIC) 2140. The switch 2130 may selectively connect the processor 2110 and the storage device 2150 or may selectively connect the NIC 2140 and the storage device 2150 under the control of the processor 2110. The NIC 2140 may include a wired interface, a wireless interface, a Bluetooth interface, an optical interface, and the like. In the embodiment, the processor 2110 and the NIC 2140 may be integrated into one device. The storage device 2150 and the NIC 2140 may also be integrated into one device.

The application server 2100 may store data requested by a user or client in one of the storage servers 2200 to 2200m via the network 2300. In addition, the application server 2100 may obtain data read-requested by a user or client from one of the storage servers 2200 to 2200m through the network 2300. For example, the application server 2100 may be implemented as a web server or a database management system (DBMS).

The application server 2100 may access the memory 2120n or the storage device 2150n included in another application server 2100n through the network 2300, or may access the memories 2220 and 2220m or storage device 2250 and 2250m included in the storage servers 2200 and 2200m through the network 2300. Accordingly, the application server 2100 may perform various operations on data stored in the application servers 2100 and 2100n and/or the storage servers 2200 and 2200m. For example, the application server 2100 may execute instructions for moving or copying data between the application servers 2100 and 2100n and/or the storage servers 2200 and 2200m. In this case, the data may be moved over the network 2300 in an encrypted state for security or privacy.

The storage server 2200 may include a processor 2210 and a memory 2220. The processor 2210 may control the overall operation of the storage server 2200, and may access the memory 2220 to execute instructions and/or data loaded in the memory 2220. The number of the processors 2210 and the number of the memories 2220 included in the storage server 2200 may be different depending on the applications. The processor 2210 and the memory 2220 may be configured as a processor-memory pair. The number of the processors 2210 and the number of the memories 2220 may be different from each other.

The processor 2210 may include a single-core processor or a multi-core processor. For example, the processor 2210 may include a general-purpose processor, a central processing unit (CPU), a graphics processing unit (GPU), a digital signal processor (DSP), a microcontroller (MCU), a microprocessor, a network processor, an embedded processor, a field programmable gate array (FPGA), an application-specific instruction set processor (ASIP), and an application-specific integrated circuit processor (ASIC).

The storage server 2200 may further include at least one storage device 2250. The number of the storage devices 2250 included in the storage server 2200 may be variously selected according to embodiments. The storage device 2250 may include a controller (CTRL) 2251, a NAND flash (NAND) 2252, and an interface (I/F) 2253. The storage device 2250 may be a DRAMless storage device that does not dispose a buffer memory outside the controller 2251.

Hereinafter, the configuration and operation of the storage device 2250 will be described in detail. The following description for the storage device 2250 may be applied to other storage devices 2150, 2150n, and 2250m.

The interface 2253 may provide a physical connection between the processor 2210 and the controller 2251, and a physical connection between the NIC 2240 and the controller 2251. For example, the interface 2253 may be implemented by a direct attached storage (DAS) method that directly connects the storage device 2250 with a dedicated cable. In addition, the interface 2253 may be implemented by various interface methods such as an advanced technology attachment (ATA), a serial ATA (SATA), an external SATA (e-SATA), a small computer small interface (SCSI), a serial attached SCSI (SAS), a peripheral component interconnection (PCI), a PCI express (PCIe), an NVM express (NVMe), an IEEE 1394, a universal serial bus (USB), a secure digital (SD) card, a multi-media card (MMC), an embedded multi-media card (eMMC), and a compact flash (CF) card.

The controller 2251 may control the overall operation of the storage device 2250. The controller 2251 may program data into the NAND flash 2252 in response to a program command, or may read data from the NAND flash 2252 in response to a read command. For example, the program command and/or read command may be provided through the processor 2210 or directly from the processor 2210 in the storage server 2200, the processor 2210m in another storage server 2200m, or the processors 2110 and 2110n in the application servers 2100 and 2100n.

The NAND flash 2252 may include a plurality of NAND flash memory cells. However, the present disclosure is not limited thereto, and the storage device 2250 may include a non-volatile memory other than the NAND flash 2252, for example, a resistive RAM (ReRAM), a phase change RAM (PRAM), or a magnetic RAM (MRAM), or may include a magnetic storage medium or an optical storage medium.

The NAND flash 2252 may operate as the non-volatile memory device 200 in FIG. 1 to FIG. 16. When the NAND flash 2252 performs a program operation on a memory block operating as a single level cell SLC, such as an SLC mode or SLC caching, it may perform a verify operation with respect to a plurality of program operations based on accumulated data to ensure speed performance and reliability.

The storage server 2200 may further include a switch 2230 and a NIC 2240. The switch 2230 may selectively connect the processor 2210 and the storage device 2250 or may selectively connect the NIC 2240 and the storage device 2250 under the control of the processor 2210. The processor 2210 and the NIC 2240 may be integrated into one device. The storage device 2250 and the NIC 2240 may be integrated into one device.

While the embodiment of the present disclosure has been described in connection with example embodiments, it is to be understood that the disclosure is not limited to the disclosed embodiments, but it is intended to cover various modifications and equivalent arrangements included within the spirit and scope of the appended claims.

What is claimed is:

1. A non-volatile memory device comprising:
a memory cell array including a first physical page and a second physical page in which each of the first and second physical pages is a unit of a program operation and the first physical page is selected by a first word line and a first string selection line and the second physical page that is selected by the first word line and a second string selection line different from the first string selection line, wherein the first physical page includes first memory cells connected to the first word line and the second physical page includes second memory cells connected to the first word line;
a row decoder configured to sequentially perform a first program operation on the first memory cells of the first physical page and perform a second program operation on the second memory cells of the second physical page;
a page buffer circuit including a sense latch and a data latch, connected to the first and second physical pages, and the page buffer circuit configured, during the first program operation, to store first data in the sense latch and in the data latch for programming the first data into the first memory cells of the first physical page, and during the second program operation, to store second data in the sense latch for programming the second data into the second memory cells of the second physical page, to perform an accumulation operation on the first and second data for generating a first accumulated data and storing the first accumulated data into the data latch, and to perform a verify operation on the first and second memory cells based on the first accumulated data; and
a control logic configured to determine whether the first and second memory cells passed the program operations based on the result of the verify operation.

2. The non-volatile memory device of claim 1, wherein the first memory cells and the second memory cells are single level cells (SLCs).

3. The non-volatile memory device of claim 1, wherein the page buffer circuit is configured to be connected to the first and second memory cells through a plurality of bit lines corresponding to the sense latch and the data latch, and is further configured to apply a precharge voltage to a first bit line among the plurality of bit lines based on the first accumulated data during the verify operation.

4. The non-volatile memory device of claim 1, wherein the first accumulated data include a plurality of accumulated bits corresponding to the plurality of bit lines, and a first accumulated bit corresponding to the first bit line among the plurality of accumulated bits is logic low when the first accumulated bit is in a programmed status.

5. The non-volatile memory device of claim 1, wherein the first accumulated data is generated based on a bit OR operation of the first data and the second data.

6. The non-volatile memory device of claim 1, wherein the memory cell array further includes a third physical page selected by the first word line and a third string selection line, and the page buffer circuit is configured to receive and store third data in the sense latch for third program operation on the third physical page.

7. The non-volatile memory device of claim 6, wherein second accumulated data is generated based on a bit OR operation of the first accumulated data and the third data.

8. The non-volatile memory device of claim 7, wherein the page buffer circuit is further to store the second accumulated data into the data latch.

9. The non-volatile memory device of claim 8, wherein the page buffer circuit is further configured to be connected to third memory cells of the third physical page through a plurality of bit lines corresponding to the sense latch and the data latch, and to apply a precharge voltage to a first bit line among the plurality of bit lines during the verify operation based on the second accumulated data.

10. The non-volatile memory device of claim 9, wherein the second accumulated data includes a plurality of accumulated bits corresponding to the plurality of bit lines, and a first accumulated bit among the plurality of accumulated bits corresponding to the first bit line is logic low when the first accumulated bit is in a programmed status.

11. The non-volatile memory device of claim 1, wherein, during the verify operation, the first and second string selection lines are configured to be selected together to perform the verify operation simultaneously on the first and second physical pages.

12. A non-volatile memory device comprising:
a memory cell array including a first physical page, a second physical page, and a third physical page in which each of the first to third physical pages is a unit of a program operation and the first physical page is selected by a first word line and a first string selection line, the second physical page that is selected by the first word line and a second string selection line, and the third physical page that is selected by the first word line and a third string selection line, wherein the first physical page includes first memory cells, the second physical page includes second memory cells, and the third physical page includes third memory cells, and the first to third memory cells are connected to the first word line;
a row decoder configured to sequentially perform a first program operation on the first memory cells of the first physical page, perform a second program operation on the second memory cells of the second physical page, and perform a third program operation on the third memory cells of the third physical page;
a page buffer circuit configured to include first to third data latches connected to the first to third physical pages, to store first data in the first latch in response to the first physical page being selected, to store second data in the second data latch in response to the second physical page being selected, and to store third data in the third data latch in response to the third physical page being selected, and to perform a verify operation based on accumulated data generated based on the first to third data; and
a control logic configured to determine whether the first to third memory cells passed the program operations based on the result of the verify operation.

13. The non-volatile memory device of claim 12, wherein the first memory cells, and the second memory cells, and third memory cells are single level cells (SLCs).

14. The non-volatile memory device of claim 13, wherein the page buffer circuit is configured to be connected to the first to third memory cells through a plurality of bit lines corresponding to the sense latch and the first to third data latches, and is further configured to apply a precharge voltage to a first bit line among the bit lines during the verify operation based on the accumulated data.

15. The non-volatile memory device of claim 14, wherein the accumulated data is generated based on a bit OR operation of the first to third data.

16. An operating method of a non-volatile memory device, comprising:
performing a setup operation of first data for a first physical page selected based on a first word line and a first string selection line;
applying a program voltage to the first physical page;
performing a setup operation of second data for a second physical page selected based on the first word line and a second string selection line different from the first string selection line;
performing a data accumulation operation based on the first and second data to generate accumulated data;
applying a program voltage to the second page;
checking whether the second page is a last page;
upon determining the second page as the last page, selecting a first page buffer among a plurality of page buffers connected to the first physical page;
performing a verify operation on a plurality of memory cells connected to the first page buffer; and
determining whether the first and second physical pages have passed program operation based on result of the verify operation.

17. The operating method of the non-volatile memory device of claim 16, further comprising
performing an erase operation on the first and second physical pages before the setup operation of the first data on the first physical page selected based on the first word line and the first string selection line.

18. The operating method of the non-volatile memory device of claim 17, wherein the checking whether the second page is the last page includes comparing the number of pages programmed after the erase operation with a predetermined number.

19. The operating method of the non-volatile memory device of claim 16, wherein each of the plurality of page buffers is connected to the first physical page through a plurality of corresponding bit lines, the accumulated data includes a plurality of accumulated bits corresponding to each of the plurality of page buffers, and the selecting of the first page buffer includes selecting a bit that is logic low from the plurality of accumulated bits.

20. The operating method of the non-volatile memory device of claim 16, wherein the performing of the verify operation includes selecting the first and second string selection lines together.
